(19) United States
(12) Patent Application Publication
(10) Pub. No.: US 2012/0019741 A1
(43) Pub. Date: Jan. 26, 2012

(54) LIGHT EMITTING DEVICE PACKAGE AND IMAGE DISPLAY DEVICE COMPRISING THE SAME

(75) Inventor: Kyung Wook PARK, Seoul (KR)

(73) Assignee: LG INNOTEK CO., LTD., Seoul (KR)

(21) Appl. No.: 13/234,710

(22) Filed: Sep. 16, 2011

(30) Foreign Application Priority Data
Sep. 17, 2010 (KR) 10-2010-0091725

(51) Int. Cl. G02F 1/1335; H01L 33/50

(52) U.S. Cl. 349/62; 257/98; 257/E33.061

(57) ABSTRACT

Disclosed is a light emitting device package including a package body provided with a first lead frame and a second lead frame, a light emitting diode electrically connected to the first lead frame and the second lead frame, a first light transfer layer surrounding the light emitting diode, the first light transfer layer made of oxide, and a second light transfer layer disposed on the first light transfer layer to change a wavelength of light transferred from the first light transfer layer, wherein the interface between the first light transfer layer and the second light transfer layer has a roughness.

This application claims the benefit of Korean Patent Application No. 10-2010-0091725, filed on Sep. 17, 2010, which is hereby incorporated by reference as if fully set forth herein.

### BACKGROUND

1. Field

Embodiments relate to a light emitting device package and an image display device including the same.

2. Discussion of the Related Art

Light emitting diodes (LEDs) are semiconductor devices which convert electric energy into light energy. Light emitting diodes have advantages of low power consumption, semipermanent life span, rapid response speed, excellent safety and environmental friendliness, as compared to conventional light sources such as fluorescent lamps and incandescent lamps. Accordingly, a great deal of research associated with use of light emitting diodes as alternatives to conventional light sources has been conducted. Use of light emitting diodes as light sources of lighting systems used indoors and outdoors such as a variety of lamps, liquid crystal display devices, electronic displays (boards) and traffic lights gradually increases.

Meanwhile, the most general method for realizing light emitting devices using conventional light emitting diodes (LEDs) is to coat LEDs with a phosphor. However, the method for coating LEDs with a phosphor has problems of deterioration in optical output and damage to LEDs by heat in the process of manufacturing light emitting diode packages.

### SUMMARY

Accordingly, embodiments are directed to a light emitting device package and an image display device including the same that substantially obviate one or more problems due to limitations and disadvantages of the related art.

Embodiments provide a light emitting device package to improve optical realize and safety of a light emitting device.

To achieve the object and other advantages in accordance with the purpose of the embodiments, as embodied and broadly described herein, provided is a light emitting device package including: a package body provided with a first lead frame and a second lead frame; a light emitting device electrically connected to the first lead frame and the second lead frame; a first light transfer layer surrounding the light emitting device, the first light transfer layer made of oxide; and a second light transfer layer disposed on the first light transfer layer to change a wavelength of light transferred from the first light transfer layer, wherein the interface between the first light transfer layer and the second light transfer layer has a roughness.

The first light transfer layer may be formed through chemical vapor deposition performed at 500° C. or lower.

The second light transfer layer may include a phosphor to change a wavelength of light emitted from the light emitting device.

The roughness may be formed by etching the surface of the first light transfer layer using a PEC method, a dry etching or a wet etching.

The roughness may have a photonic crystal structure.

The oxide may include at least one of silicone oxide, oxynitride of aluminum oxide.

The light emitting device may include: a light emitting structure including a first conductive semiconductor layer, an active layer and a second conductive semiconductor layer; a first electrode disposed on the first conductive semiconductor layer; and a second electrode disposed on the second conductive semiconductor layer.

The light emitting device may be electrically connected to the first lead frame and the second lead frame by wire bonding, die bonding or flip chip bonding.

The package body may have a cavity, the light emitting device may be disposed on the bottom of the cavity and the first light transfer layer may be disposed on at least a part of the cavity.

The top of the phosphor layer may be higher than the top of the package body.

The phosphor layer may have a non-uniform thickness.

The phosphor layer may have a non-uniform longitudinal section shape.

In accordance with another aspect, provided is a light emitting device package including: a package body provided with a first lead frame and a second lead frame; a light emitting device electrically connected to the first lead frame and the second lead frame; and an oxide resin layer surrounding the light emitting device, wherein the oxide resin layer is formed by chemical vapor deposition performed at 500° C. or lower and contains oxide.

In accordance with another aspect, provided is an image display device including: a light source module including a circuit substrate and a light emitting device package electrically connected to the circuit substrate; a light guide plate to transfer light emitted from the light source module; and a panel including a first transparent substrate, a second transparent substrate, a plurality of liquid crystals between the first transparent substrate and the second transparent substrate, and a polarization plate disposed on each of the first transparent substrate and the second transparent substrate, wherein the light emitting device package includes: a package body provided with a first lead frame and a second lead frame; a light emitting device electrically connected to the first lead frame and the second lead frame; a first light transfer layer surrounding the light emitting device, the first light transfer layer made of oxide; and a second light transfer layer disposed on the first light transfer layer to change a wavelength of light transferred from the first light transfer layer, wherein the interface between the first light transfer layer and the second light transfer layer has a roughness.

It is to be understood that both the foregoing general description and the following detailed description of the present embodiments are exemplary and explanatory and are intended to provide further explanation of the embodiments as claimed.

### BRIEF DESCRIPTION OF THE DRAWINGS

The accompanying drawings, which are included to provide a further understanding of the embodiments and are incorporated in and constitute a part of this application, illustrate embodiment(s) and along with the description serve to explain the principle of the invention. In the drawings:

FIG. 1 is a cross-sectional view illustrating a light emitting diode package according to a first embodiment;

FIGS. 2A to 2D are cross-sectional views illustrating a method for manufacturing a light emitting device package;

FIG. 3 is a cross-sectional view illustrating a light emitting device package according to a second embodiment;

FIGS. 4A and 4B are cross-sectional views illustrating a light emitting device package according to a third embodiment and a fourth embodiment, respectively;

FIG. 5 is a cross-sectional view illustrating a light emitting diode package according to a fifth embodiment;

FIG. 6 is a view illustrating a tray to deposit an oxide resin layer according to one embodiment;

FIG. 7 is a sectional view illustrating a head lamp including the light emitting device package according to one embodiment; and

FIG. 8 is a sectional view illustrating an image display device including the light emitting device package according to one embodiment.

### DETAILED DESCRIPTION

Reference will now be made in detail to preferred embodiments, examples of which are illustrated in the accompanying drawings.

Prior to description of the embodiments, it will be understood that, when an element is referred to as being formed “on or under” another element, the two elements may directly contact each other or may be indirectly disposed such that at least one intervening element is interposed therebetween. Further, “on or under” each element is described based on the drawings.

In the drawings, the thicknesses or sizes of respective layers are exaggerated, omitted or schematically illustrated for convenience and clarity of description. Therefore, the sizes of respective elements do not wholly reflect actual sizes thereof.

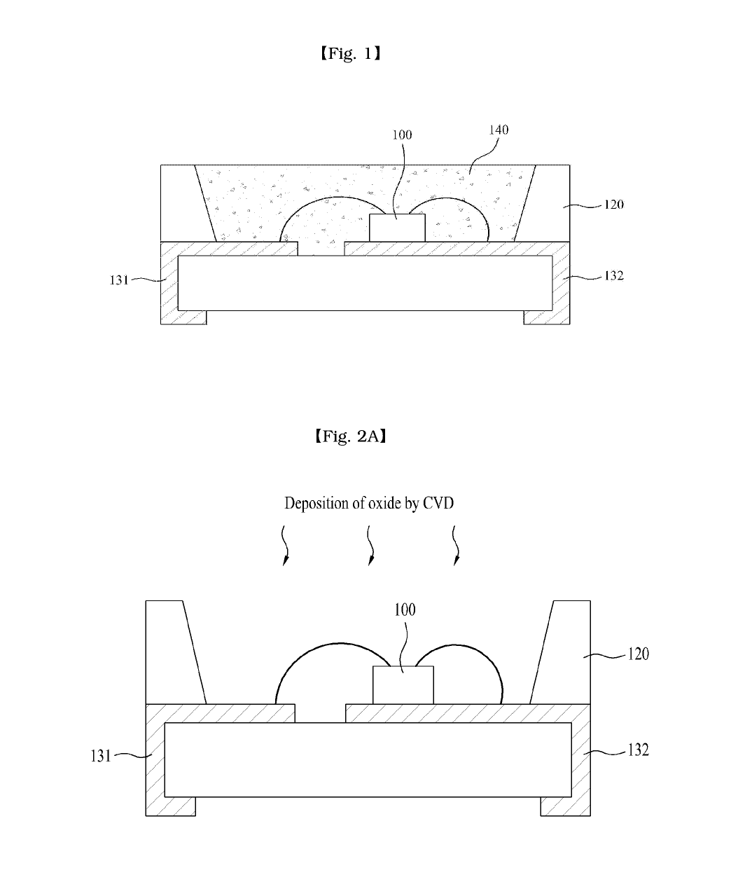

FIG. 1 is a cross-sectional view illustrating a light emitting diode package according to a first embodiment.

Referring to FIG. 1, the light emitting device package according to the first embodiment includes a package body 120, a first lead frame 131 and a second lead frame 132 mounted on the package body 120, a light emitting device 100 mounted on the package body 120 and electrically connected to the first lead frame 131 and the second lead frame 132, and an oxide resin layer 140 surrounding the light emitting device 100. The light emitting device 100 may include a light emitting diode.

The package body 120 may contain at least one of a PPA resin, a silicone material, a synthetic resin material or a metal material, and an inclined plane may be formed around the light emitting device 100 to improve light extraction efficiency.

The package body 120 has a cavity and the light emitting device 100 is disposed on the bottom of the cavity and the oxide resin layer 140 is disposed on at least a part of the cavity.

The first lead frame 131 and the second lead frame 132 are electrically separated from each other and supply power to the light emitting device 100.

In addition, the first lead frame 131 and the second lead frame 132 reflect light emitted from the light emitting device 100 to improve optical efficiency and discharge heat emitted from the light emitting device 100 to the outside.

The light emitting device 100 may be mounted on the package body 120, or on the first lead frame 131 or the second lead frame 132.

The light emitting device 100 includes a light emitting structure including a first conductive semiconductor layer, an active layer and a second conductive semiconductor layer, a first electrode disposed on the first conductive semiconductor layer, and a second electrode disposed on the second conductive semiconductor layer.

The light emitting device 100 may be electrically connected to the first lead frame 131 and the second lead frame 132 by wire bonding. In addition, alternatively, the light emitting device 100 may be electrically connected to the first lead frame 131 and the second lead frame 132 by flip chip or die bonding.

The oxide resin layer 140 is laminated on the light emitting device 100 to surround and protect the light emitting device 100.

The oxide resin layer 140 may be made of a light-transmitting oxide. For example, the oxide resin layer 140 may be composed of a silicon oxide (SiO₂) layer, an oxynitride layer, or an aluminum oxide layer.

Alternatively, the oxide resin layer 140 may be formed by depositing a light-transmitting insulating material through chemical vapor deposition at a low temperature.

For example, the oxide resin layer 140 is formed by depositing SiO₂ on the light emitting device 100 at 500° C. or lower through chemical vapor deposition.

The oxide resin layer 140 is made of light-transmitting oxide of the light emitting device 100 and thus effectively minimizes deterioration in light extraction. The oxide resin layer 140 effectively protects the light emitting device 100 after the light emitting device 100 is electrically connected to the first lead frame 131 and the second lead frame 132. In addition, when the oxide resin layer 140 is deposited through chemical vapor deposition at a low temperature, generation of heat is minimized and the light emitting device 100 can be protected against thermal damage which may occur during subsequent processes.

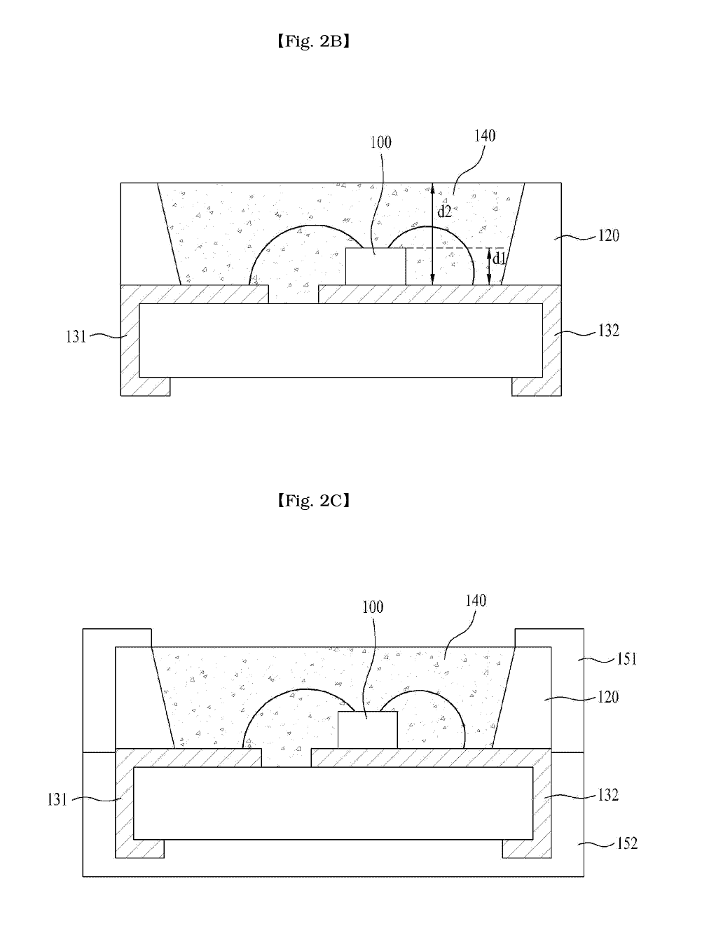

FIGS. 2A to 2D are cross-sectional views illustrating a method for manufacturing a light emitting device package.

Referring to FIG. 2A, first, as shown in FIG. 2A, a first lead frame 131 and a second lead frame 132 are mounted on a package body 120 and a light emitting device 100 is mounted on the package body 120, or on the first lead frame 131 or the second lead frame 132.

Then, the light emitting device 100 is electrically connected to the first lead frame 131 and the second lead frame 132.

At this time, the light emitting device 100 may be connected to the first lead frame 131 and the second lead frame 132 by wire bonding. Alternatively, the light emitting device 100 may be electrically connected thereto by flip chip or die bonding.

Then, the oxide resin layer 140 is deposited on the light emitting device 100.

At this time, the oxide resin layer 140 may be formed by depositing light-transmitting oxide. For example, the oxide resin layer 140 may contain a silicone oxide (SiO₂) layer, an oxynitride layer, or an aluminum oxide layer, or a combination thereof.

Alternatively, the oxide resin layer 140 may be formed by depositing light-transmitting oxide through chemical vapor deposition at a low temperature.

For example, the oxide resin layer 140 may be formed by depositing SiO₂ on the light emitting device 100 through chemical vapor deposition which is performed at 500° C. or lower. The oxide resin layer 140 deposited at a low temperature has slight film stress and slight stress by thermal damage occurring during operation of the light emitting device, thus exhibiting superior reliability, as compared to films deposited at high temperatures.

The oxide resin layer 140 contains light-transmitting oxide of the light emitting device 100 and thus effectively minimizes deterioration in light extraction, and overall effectively protects the light emitting device 100 after the light emitting device 100 is electrically connected to the first lead frame 131 and the second lead frame 132.

FIG. 2A is a view illustrating an example in which the oxide resin layer 140 is deposited through low-temperature chemical vapor deposition.

Referring to FIG. 2B, the light emitting device package includes the oxide resin layer 140 provided on the light emitting device 100.

The oxide resin layer 140 may be deposited such that it surrounds the light emitting device 100 to protect the light emitting device 100, although the embodiment is not limited in terms of deposited shape or thickness.

The thickness of the oxide resin layer 140 deposited may be varied in some embodiments. The thickness of the light emitting device 100 may be determined as an experimental value to protect the oxide resin layer 140 against thermal or physical damage.

For example, when the thickness (d1) of the light emitting device 100 is 4 μm, the thickness (d2) of the oxide resin layer 140 may be 10 μm and the thickness (d2) of the oxide resin layer 140 may be 2 or 3-times of the thickness (d1) of the light emitting device 100.

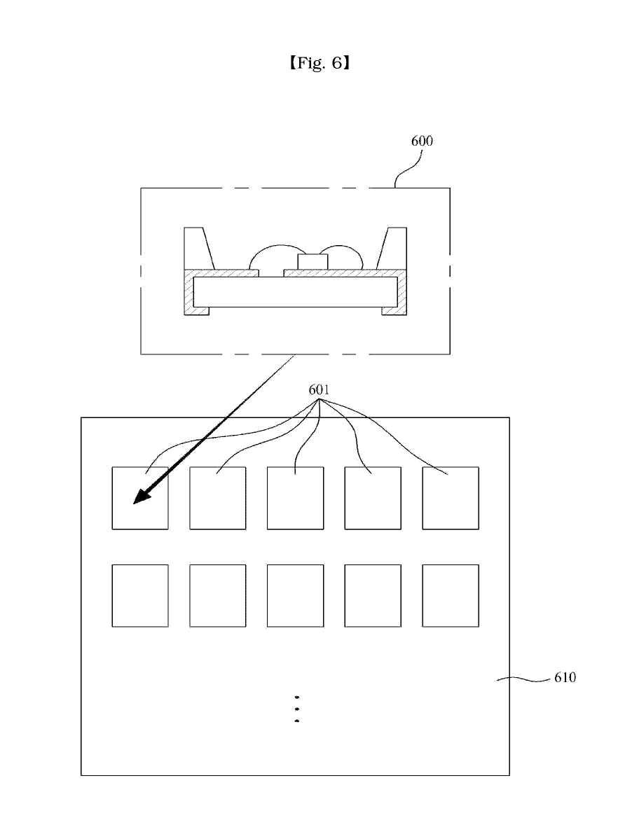

The deposition of the oxide resin layer 140 as shown in FIG. 2B may be simultaneously performed in a plurality of light emitting device packages and the embodiment of a tray to deposit the oxide resin layer 140 in the light emitting device packages will be described with reference to FIG. 6 below.

In addition, as shown in FIG. 2C, trays 151 and 152 are mounted to form a phosphor layer 160 on the oxide resin layer 140. Alternatively, the trays may be composed of an upper tray 151 and a lower tray 152.

In addition, as shown in FIG. 2D, the phosphor layer 160 is formed on the oxide resin layer 140. The phosphor layer 160 is formed to obtain output light of a specific wavelength range, and phosphor particles may be dispersed in the phosphor layer 160.

The phosphor layer 160 changes a wavelength of light, which is formed in the light emitting device 100 and passes through the oxide resin layer 140 and allows a specific wavelength of light to be emitted.

For example, when the light emitting device 100 emits blue light, the oxide resin layer 140 includes a yellow phosphor to allow white light to be emitted.

That is, the oxide resin layer 140 may serve as a first light transfer layer which protects the light emitting device 100 and improves light transfer efficiency, and the phosphor layer 160 may serve as a second light transfer layer which changes wavelength of light which is emitted from the light emitting device 100 and passes through the first light transfer layer and thus transfers the same to the outside.

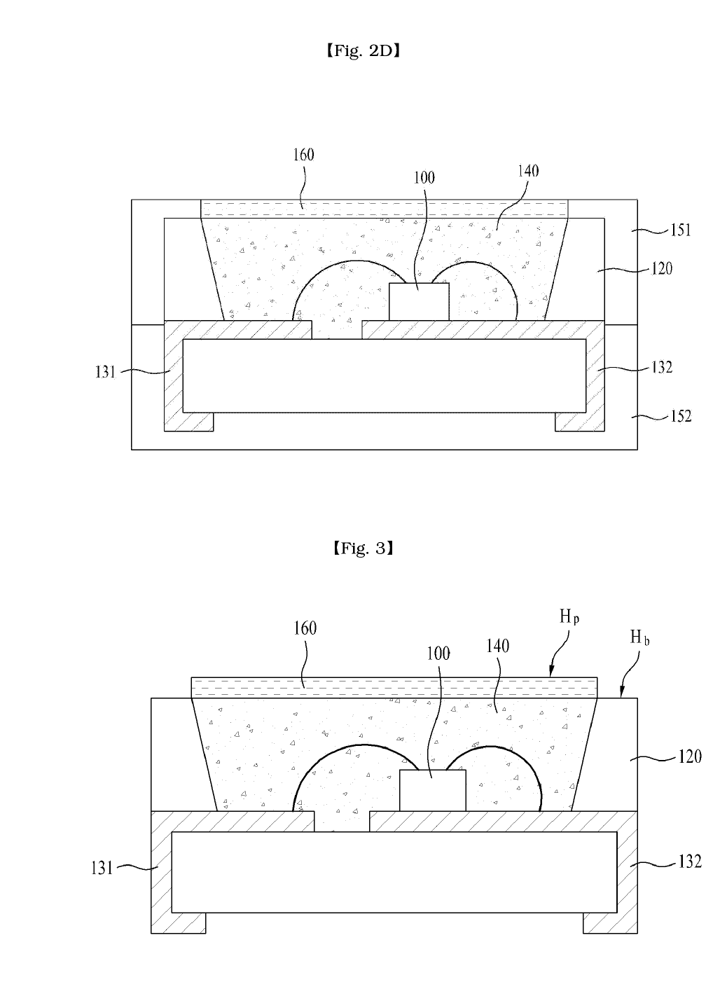

After the phosphor layer 160 is formed, the trays 151 and 152 are removed to manufacture a light emitting device package as shown in FIG. 3.

FIG. 3 is a cross-sectional view illustrating a light emitting device package according to a second embodiment. FIG. 3 illustrates a configuration in which the phosphor layer 160 is added to the light emitting device package of FIG. 1.

The light emitting device package according to the second embodiment includes the oxide resin layer 140 disposed between the light emitting device 100 and the phosphor layer 160, thus advantageously preventing pores which may be generated around the light emitting device 100 and minimizing deterioration in light extraction caused by degeneration of the phosphor layer adjacent to the light emitting device 100, when the phosphor layer 160 is directly contacted to on the light emitting device 100.

That is, the light emitting device package according to the second embodiment includes the oxide resin layer 140 disposed between the light emitting device 100 and the phosphor layer 160, thus preventing the light emitting device 100 from directly contacting the phosphor layer, and coming in contact with these elements through the heat-resistant oxide resin layer 140, thereby providing a light emitting device package which improves safety of the light emitting device.

In addition, in the light emitting device package according to the second embodiment, since the oxide resin layer 140 is deposited through low-temperature chemical vapor deposition, generation of heat is minimized and thermal damage to the light emitting device which occurs during molding of the light emitting device package is thus minimized. In addition, the top (Hₚ) of the phosphor layer 160 may be higher than the top (H_{b}) of the package body 120.

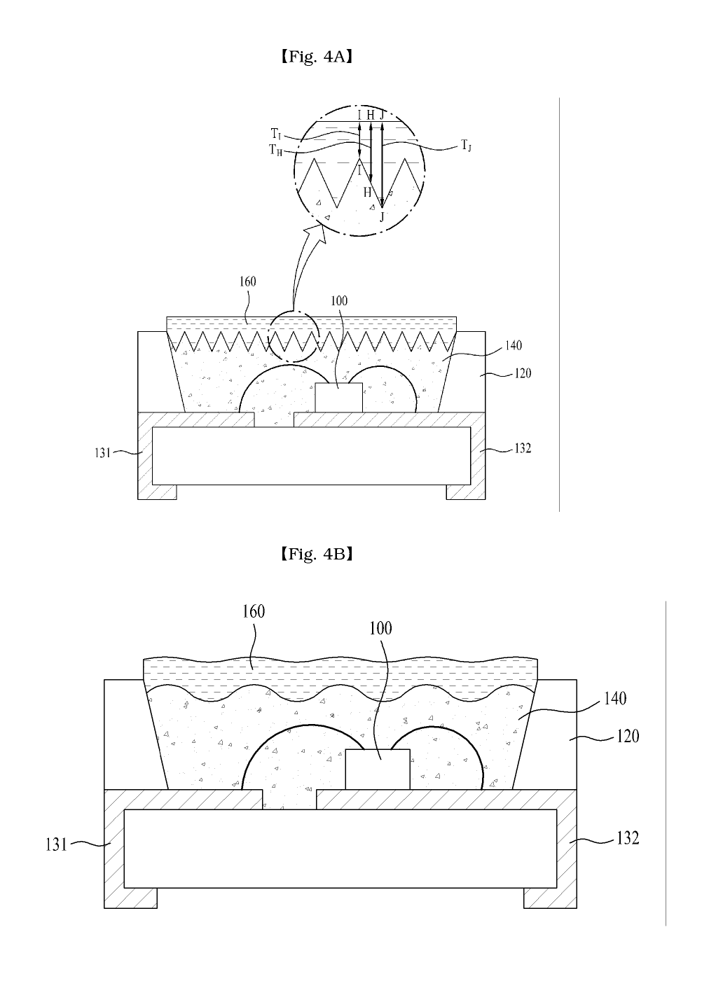

FIGS. 4A and 4B are cross-sectional view illustrating a light emitting device package according to third and fourth embodiments, respectively. Referring to FIG. 4, a roughness may be formed on the interface between the oxide resin layer 140 and the phosphor layer 160.

The roughness of the surface of the oxide resin layer 140 may be formed using a PEC method, or by forming a mask, followed by etching. At this time, the shape of micro-size roughness can be controlled by controlling the amount of etchant, the intensity of ultraviolet (UV) light, exposure time and the like.

At this time, the micro-size roughness may be formed using an etching process using a mask. The etching process using a mask is carried out in accordance with the following method. The oxide resin layer 140 is coated with a photoresist and is exposed to light using a mask. After the light-exposure process, the resulting layer is developed to form an etching pattern. As a result of the process as mentioned above, the etching pattern is formed on the oxide resin layer 140 and an etching process is performed to form a roughness on the oxide resin layer 140. The roughness increases a surface area of the oxide resin layer 140 and the phosphor layer 160 and thus improves light transmittance. Commonly, it is preferable that the numbers of grooves and protrusions present in the roughness are as high as possible.

The phosphor layer 160 may have a non-uniform thickness. That is, the heights T_{H}, T_{I} and T_{J} from the inclined plane, the groove and the protrusion of the roughness of the oxide resin layer 140 to the surface of the phosphor layer 160 may be different. In addition, the longitudinal sections taken along the I-I, H-H and J-J axises at respective points of the phosphor layer 160 may have different lengths and shapes.

As shown in FIG. 4B, the oxide resin layer 140 has a rough surface. The roughness may be formed on the surface of the oxide layer 140 in the process of curing without performing the etching process. At this time, the surface of the phosphor layer 160 formed on the oxide resin layer 140 may be flattened. Also, the roughness present on the surface of the oxide resin layer 140 may impart slight roughness to the surface of the phosphor layer 150.

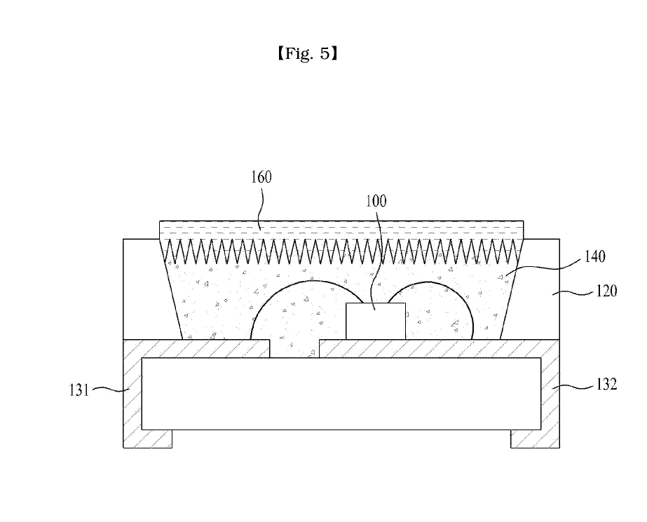

FIG. 5 is a cross-sectional view illustrating a light emitting diode package according to a fifth embodiment. Referring to FIG. 5, a two-dimensional photonic crystal is present on the interface between the oxide resin layer 140 and the phosphor layer 160. This structure is obtained by periodically arranging at least two dielectrics having different indexes of refraction at an interval equal to half the wavelength of light to be emitted. At this time, respective dielectrics may have an identical pattern.

The photonic crystal forms a photonic band gap on the surface of the oxide resin layer 140 to control flow of light.

As mentioned above, the light emitting device package according to the embodiment advantageously provides a light emitting device with improved light extraction efficiency by patterning the oxide resin layer 140, followed by forming the phosphor layer 160.

FIG. 6 is a sectional view illustrating a tray to deposit the oxide resin layer according to one embodiment. As shown in FIG. 6, the deposition of the oxide resin layer 140 shown in FIG. 2 may be simultaneously carried out in a plurality of light emitting device packages 601 disposed in the tray 610.

In addition, the light emitting device package may be provided with a plurality of light emitting devices but is not limited thereto.

The light emitting device package according to the embodiment is arrayed in plural on a substrate, and a light guide plate, a prism sheet, a diffusion sheet and the like as optical members may be disposed on a light passage of the light emitting device package. The light emitting device package, the substrate and the optical members may serve as a light unit. In another embodiment, display devices, indicator devices and lighting systems including the semiconductor light emitting device or the light emitting device package mentioned in the embodiments may be realized. For example, the lighting systems may include lamps, streetlamps and the like. Hereinafter, a heat lamp and a backlight unit as embodiments of a lighting system in which the light emitting device package is disposed will be described.

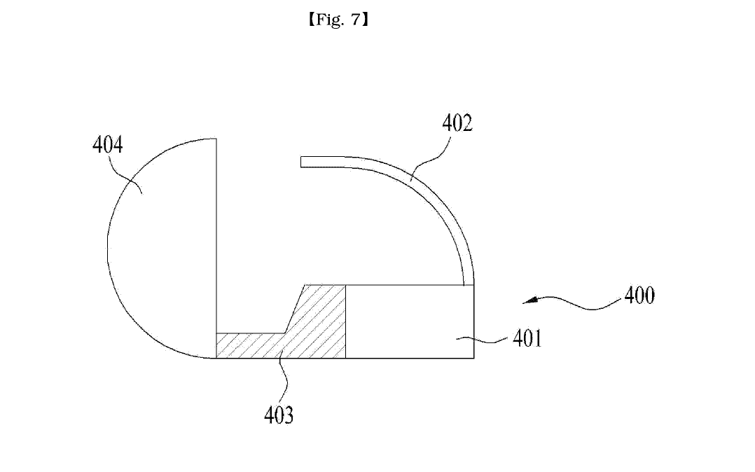

FIG. 7 is a sectional view illustrating a head lamp including the light emitting device package according to one embodiment.

In the head lamp 400 according to this embodiment, light emitted from a light emitting device module 401 in which the light emitting device package is disposed is reflected by a reflector 402 and a shade 403, transmits a lens 404 and travels towards the front of the body.

As mentioned above, light extraction efficiency of the light emitting device used for the light emitting device module 401 may be improved and the overall optical properties of the head lamp may thus be improved.

The light emitting device package contained in the light emitting device module 401 may be provided with a plurality of light emitting devices, but is not limited thereto.

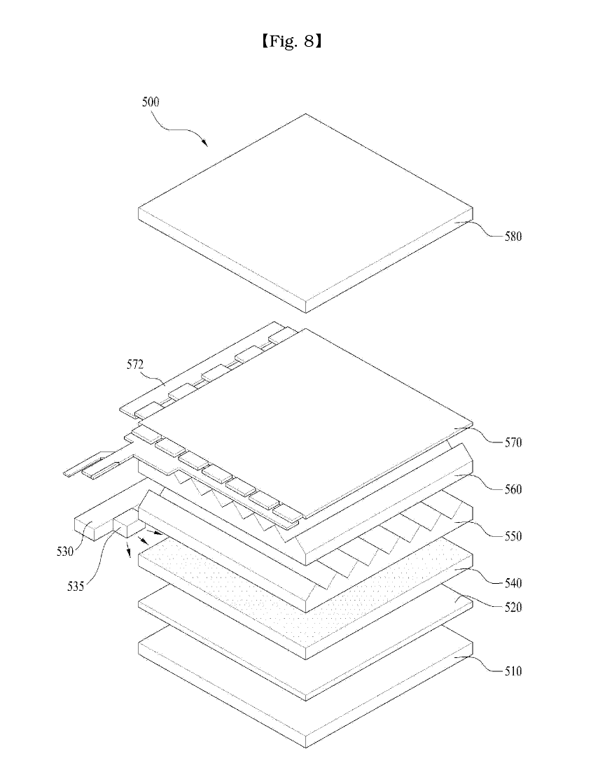

FIG. 8 is a sectional view illustrating an image display device including the light emitting device package according to one embodiment.

As illustrated in FIG. 8, the display device 500 according to this embodiment includes a light source module, a reflector 520 disposed on a bottom cover 510, a light guide plate 540 disposed in front of the reflector 520 to guide light emitted from the light source module toward the front of the display device, a first prism sheet 550 and a second prism sheet 560 disposed in front of the light guide plate 540, a panel 570 disposed in front of the second prism sheet 560, and a color filter 580 disposed in front of the panel 570.

The light source module includes a circuit substrate 530 and a light emitting device package 535 disposed thereon. The circuit substrate 530 may be a PCB or the like and the light emitting device package 535 has been described above.

The bottom cover 510 may accept constituent components of the display device 500. The reflector 520 may be provided as an additional component, as shown in the drawing, or as a highly reflective material coated on the rear surface of the light guide plate 540, or the front surface of the bottom cover 510.

The reflector 520 may use a highly reflective and ultrathin material. Examples of such material include polyethylene terephtalate (PET).

The light guide plate 540 scatters light emitted from the light emitting device package module to uniformly distribute the light over the overall screen region of the liquid crystal display. Accordingly, the light guide plate 530 is made of a material having a high index of refraction and a high transmittance and examples thereof include polymethylmethacrylate (PMMA), polycarbonate (PC), polyethylene (PE) and the like. In addition, when the light guide plate 540 is omitted, an air guide-type display device may be realized.

The first prism sheet 550 is formed using a light-transmitting elastic polymer on one surface of a support film, and the polymer may have a prism layer in which a plurality of three-dimensional patterns is repeatedly formed. The plurality of patterns may be provided in the form of stripes including repeatedly disposed protrusions and grooves.

The direction of the protrusions and grooves on one surface of the support film in the second prism sheet 560 may be perpendicular to the direction of protrusions and grooves on one surface of the support film in the first prism sheet 550. This aims to uniformly distribute light transferred from the light source module and the reflective sheet in all directions of the panel 570.

In this embodiment, the first prism sheet 550 and the second prism sheet 560 constitute an optical sheet. The optical sheet may be provided as the other combination, such as a combination of micro lens arrays, a combination of a diffusion sheet and a micro lens array, or a combination of one prism sheet and a micro lens array.

A liquid crystal display may be disposed in the panel 570 and a liquid crystal display as well as other display devices requiring a light source may be utilized.

The panel 570 has a structure in which liquid crystal is interposed between a pair of transparent substrates and a polarization plate is mounted on each transparent substrate to utilize polarization of light. Liquid crystal has an intermediate property between a liquid and a solid. Liquid crystal as a flowable organic molecule like a liquid is regularly disposed like a crystal and the molecular arrangement thereof is changed by an exterior electric field. Based on this property, images are displayed.

The liquid crystal display panel used for the display device may be an active matrix-type panel and uses a transistor as a switch to control voltage supplied to each pixel.

A color filter 580 is provided on the front surface of the panel 570 to selectively transmit red, green or blue light in each pixel, among light projected from the panel 570, and thereby to display an image.

As apparent from the fore-going, the embodiments provide a light emitting device package to improve optical efficiency and realize safety of a light emitting device.

It will be apparent to those skilled in the art that various modifications and variations can be made in the embodiments without departing from the spirit or scope of the embodiments. Thus, it is intended that the embodiments covers the modifications and variations of the embodiments provided they come within the scope of the appended claims and their equivalents.

What is claimed is:

1. A light emitting device package comprising:
a package body provided with a first lead frame and a second lead frame;
a light emitting diode electrically connected to the first lead frame and the second lead frame;
a first light transfer layer surrounding the light emitting diode, the first light transfer layer made of oxide; and
a second light transfer layer disposed on the first light transfer layer to change a wavelength of light transferred from the first light transfer layer,
wherein the interface between the first light transfer layer and the second light transfer layer has a roughness.

2. The light emitting device package according to claim 1, wherein the first light transfer layer is formed through chemical vapor deposition performed at 500° C. or lower.

3. The light emitting device package according to claim 1, wherein the second light transfer layer comprises a phosphor to change a wavelength of light emitted from the light emitting diode.

4. The light emitting device package according to claim 1, wherein the roughness is formed by etching the surface of the first light transfer layer using a PEC method, a dry etching or wet etcing.

5. The light emitting device package according to claim 1, wherein the roughness has a photonic crystal structure.

6. The light emitting device package according to claim 1, wherein the oxide comprises at least one of silicone oxide, oxynitride or aluminum oxide.

7. The light emitting device package according to claim 1, wherein the light emitting diode comprises:
a light emitting structure including a first conductive semiconductor layer, an active layer and a second conductive semiconductor layer;
a first electrode disposed on the first conductive semiconductor layer; and
a second electrode disposed on the second conductive semiconductor layer.

8. The light emitting device package according to claim 1, wherein the light emitting diode is electrically connected to the first lead frame and the second lead frame by wire bonding, die bonding or flip chip bonding.

9. The light emitting device package according to claim 1, wherein the package body has a cavity, the light emitting diode is disposed on the bottom of the cavity and the first light transfer layer is disposed on at least a part of the cavity.

10. The light emitting device package according to claim 1, wherein the top of the phosphor layer is higher than the top of the package body.

11. The light emitting device package according to claim 1, wherein the phosphor layer has a non-uniform thickness.

12. The light emitting device package according to claim 1, wherein the phosphor layer has a non-uniform longitudinal section shape.

13. A light emitting device package comprising:
a package body provided with a first lead frame and a second lead frame;
a light emitting diode electrically connected to the first lead frame and the second lead frame; and
an oxide resin layer surrounding the light emitting diode, wherein the oxide resin layer is formed by chemical vapor deposition performed at 500° C. or lower and contains oxide.

14. The light emitting device package according to claim 13, further comprising: a phosphor layer disposed on the oxide resin layer to convert the wavelength of light transferred from the oxide resin layer, wherein the interface between the oxide resin layer and the phosphor layer has a roughness.

15. The light emitting device package according to claim 14, wherein the top of the phosphor layer is higher than the top of the package body.

16. The light emitting device package according to claim 13, wherein the package body has a cavity, the light emitting diode is disposed on the bottom of the cavity and the oxide resin layer is disposed on at least a part of the cavity.

17. The light emitting device package according to claim 13, wherein the phosphor layer has a non-uniform longitudinal section shape.

18. An image display device comprising:
a light source module including a circuit substrate and a light emitting device package electrically connected to the circuit substrate;
a light guide plate to transfer light emitted from the light source module; and
a panel including a first transparent substrate, a second transparent substrate, a plurality of liquid crystals between the first transparent substrate and the second transparent substrate, and a polarization plate disposed on each of the first transparent substrate and the second transparent substrate,
wherein the light emitting device package comprises:
a package body provided with a first lead frame and a second lead frame;
a light emitting diode electrically connected to the first lead frame and the second lead frame;
a first light transfer layer surrounding the light emitting diode, the first light transfer layer made of oxide; and
a second light transfer layer disposed on the first light transfer layer to change a wavelength of light transferred from the first light transfer layer,
wherein the interface between the first light transfer layer and the second light transfer layer has a roughness.

19. The image display device according to claim 18, wherein the first light transfer layer is formed through chemical vapor deposition performed at 500° C. or lower.

20. The image display device according to claim 17, wherein the oxide comprises at least one of silicone oxide, oxynitride or aluminum oxide.
